(19) United States
(12) Patent Application Publication
(10) Pub. No.: US 2025/0149365 A1
(43) Pub. Date: May 8, 2025

(54) UNIT HANGING APPARATUS, OVERHEAD HOIST TRANSPORT, AND OVERHEAD HOIST TRANSPORT FACILITY

(71) Applicant: SEMES CO., LTD., Cheonan-si (KR)

(72) Inventors: Jong Hyun KIM, Asan-si (KR); Jae Hyun LEE, Suwon-si (KR); Ki Tae NOH, Seongnam-si (KR)

(21) Appl. No.: 18/909,919

(22) Filed: Oct. 8, 2024

(30) Foreign Application Priority Data
Nov. 8, 2023 (KR) 10-2023-0153393

(51) Int. Cl. H01L 21/677; H01L 21/687

(52) U.S. Cl. CPC H01L 21/67733; H01L 21/68742

(57) ABSTRACT

The present disclosure provides a unit hanging apparatus, an overhead hoist transport, and an overhead hoist transport facility.

A unit hanging apparatus according to an embodiment of the present disclosure includes a through-hole formed in a hoist body of a hoist unit; and a hanging unit formed in a hand unit suspended from a hoist belt of the hoist unit, and having a hanging pin that passes through the through-hole and is hung on the hoist body so that the hand unit is hung on the hoist unit.

### CROSS-REFERENCE TO RELATED APPLICATION(S)

This application claims benefit of priority to Korean Patent Application No. 10-2023-0153393 filed on Nov. 8, 2023 in the Korean Intellectual Property Office, the disclosure of which is incorporated herein by reference in its entirety.

### BACKGROUND

### 1. Field

The present disclosure relates to a unit hanging apparatus, an overhead hoist transport, and an overhead hoist transport facility, used in a facility for manufacturing a semiconductor.

### 2. Description of Related Art

In a facility for manufacturing a semiconductor, substrates stored in a stocker may usually be loaded into a closed carrier such as a front opening unified pod (FOUP), a front opening shipping box (FOSB), a storage box, or the like, or an open carrier such as an open cassette or the like.

These carriers may be transported by an overhead hoist transport (OHT) travelling along a rail installed on a ceiling.

However, in order for the overhead hoist transport to carry a hand unit while travelling, a stall torque supporting load of the hand unit and load of the carrier by a hoist belt may be generated.

In order to support the stall torque, requirements of a motor may sometimes be high, but when high load is supported for a long time, deterioration may occur due to a high load rate.

Specifically, when the overhead hoist transport travels, the hand unit may be located in a raised state, and load of the hand unit and load of the carrier may be supported by the hoist belt while travelling. At this time, stall torque may be generated in a hoist motor of a hoist unit, and when the overhead hoist transport travels for a long period of time while carrying the carrier, it may cause deterioration due to the load.

### Prior Art Literature

### Patent Document(s)

(Patent Document 1) Korea Patent Publication No. 10-2019-0141408

### SUMMARY

An aspect of the present disclosure is to provide a unit hanging apparatus, an overhead hoist transport, and an overhead hoist transport facility, configured to hang a hand unit on a hoist unit.

According to an aspect of the present disclosure, a unit hanging apparatus includes a through-hole formed in a hoist body of a hoist unit; and a hanging unit formed in a hand unit suspended from a hoist belt of the hoist unit, and having a hanging pin that passes through the through-hole and is hung on the the hoist body so that the hand unit is hung on the hoist unit.

The through-hole may be disposed vertically, and the hanging unit may include the hanging pin disposed vertically on an upper side of the hand unit; and a driving member installed on the hand unit and connected to the hanging pin to rotate the hanging pin, and the hanging pin is hung on an upper edge of the through-hole when the hanging pin rotates and descends after passing through the through-hole.

The hanging pin may include a pin body formed in a cylindrical shape; and a pin head formed on an upper end portion of the pin body and formed to extend laterally more than the pin body.

the through-hole may have a cross-sectional shape that allows the pin head to pass through, but prevents the pin head from passing through in the reverse direction after passing through and rotating.

The pin head may be formed to taper in an upward direction.

The hanging unit may further include a guide member installed in a lower portion of the through-hole in the hoist body and having a guide hole guiding the hanging pin to the through-hole.

An internal space of a lower opening of the guide hole may be formed to expand in a downward direction to guide introduction of the hanging pin.

The hanging unit may further include a stopper formed on the hoist body to limit rotation of the hanging pin.

The hanging unit may further include a connecting bracket connecting the hanging pin and the hand unit, wherein the connecting bracket includes a bracket body installed in the hand unit and having a bracket hole formed through which the hanging pin passes; and a bearing installed in the bracket hole and to which the hanging pin is rotatably connected.

The through-hole may be provided as a plurality of through-holes, the plurality of through-holes may be disposed at a predetermined interval from each other in the hoist body, and the hanging unit may be provided as a plurality of hanging units, the plurality of hanging units may be disposed at a predetermined interval from each other on the hand unit to correspond to the plurality of through-holes.

According to another aspect of the present disclosure, an overhead hoist transport includes a travelling unit; a hoist unit installed on the travelling unit and having a hoist belt; a hand unit suspended from the hoist belt; and a unit hanging apparatus formed in the hoist unit and the hand unit such that the hand unit is hung on the hoist unit, wherein the unit hanging apparatus includes a through-hole formed in a hoist body of the hoist unit; and a hanging unit having a hanging pin formed in the hand unit and passing through the through-hole and hung on the hoist body.

According to another aspect of the present disclosure, an overhead hoist transport facility includes a rail installed on a ceiling; and an overhead hoist transport disposed on the rail, wherein the overhead hoist transport includes a travelling unit travelling along the rail; a hoist unit installed on the travelling unit and having a hoist belt; a hand unit suspended from the hoist belt; and a unit hanging apparatus formed in the hoist unit and the hand unit such that the hand unit is hung on the hoist unit, wherein the unit hanging apparatus includes a through-hole formed in a hoist body of the hoist unit; and a hanging unit having a hanging pin formed in the hand unit and passing through the through-hole and hung on the hoist body, wherein the hanging unit includes the hanging pin disposed vertically on an upper side of the hand unit; a driving member installed on the hand unit and connected to the hanging pin to rotate the hanging pin; and a connecting bracket connecting the hanging pin and the hand unit, and wherein the hanging pin is hung on an upper edge of the through-hole when the hanging pin rotates and descends after passing through the through-hole.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating an overhead hoist transport facility according to an embodiment of the present disclosure.

FIGS. 2 and 3 are enlarged views of a unit hanging apparatus when a hand unit descends and ascends in the overhead hoist transport facility of FIG. 1.

FIGS. 4 to 6 are cross-sectional views illustrating rotating, descending, and hanging of a hanging pin in the unit hanging apparatuses of FIGS. 2 and 3.

FIG. 7 is a view illustrating a process in which the hand unit of FIG. 2 ascends and is then hung on a hoist unit.

FIG. 8 is a view illustrating a process in which the hand unit of FIG. 3 is released from a hoist unit and then descends.

### DETAILED DESCRIPTION

Hereinafter, a preferred embodiment will be described in detail such that those skilled in the art may easily practice the present disclosure with reference to the accompanying drawings. However, in describing a preferred embodiment of the present disclosure in detail, when it is determined that a detailed description of a related known function or configuration may unnecessarily obscure the gist of the present disclosure, the detailed description will be omitted. In addition, the same reference numerals may be used throughout the drawings for portions having similar functions and actions. In addition, in the present specification, terms such as ‘on,’ ‘upper portion,’ ‘upper surface,’ ‘below,’ ‘lower portion,’ ‘lower surface,’ ‘side surface,’ and the like may be based on the drawings, and components may be actually changed, depending on a direction in which the components are disposed.

In addition, throughout the specification, when a portion is ‘connected’ to another portion, it may be not only ‘directly connected’, but also ‘indirectly connected’ to other components therebetween. In addition, ‘including’ a certain component means that other components may be further included, rather than excluding other components, unless otherwise stated.

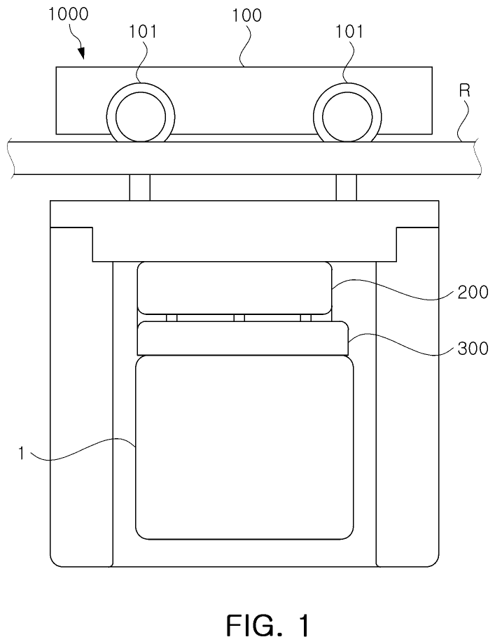

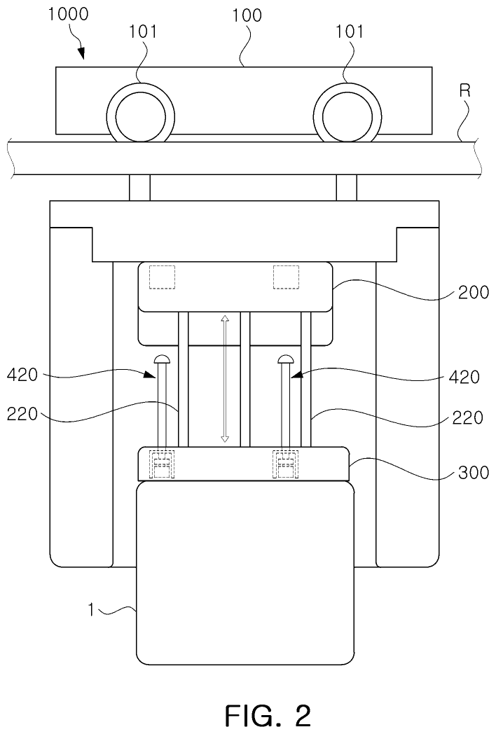

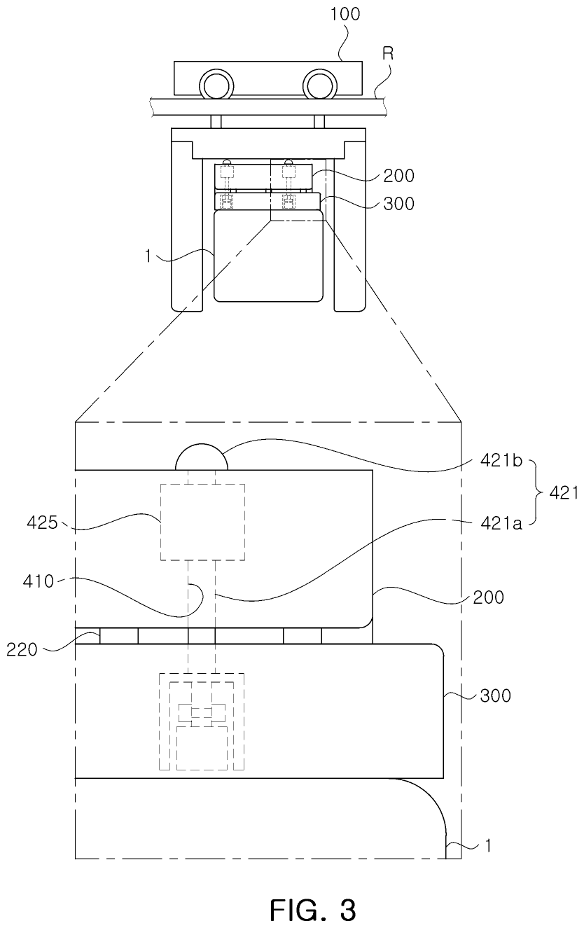

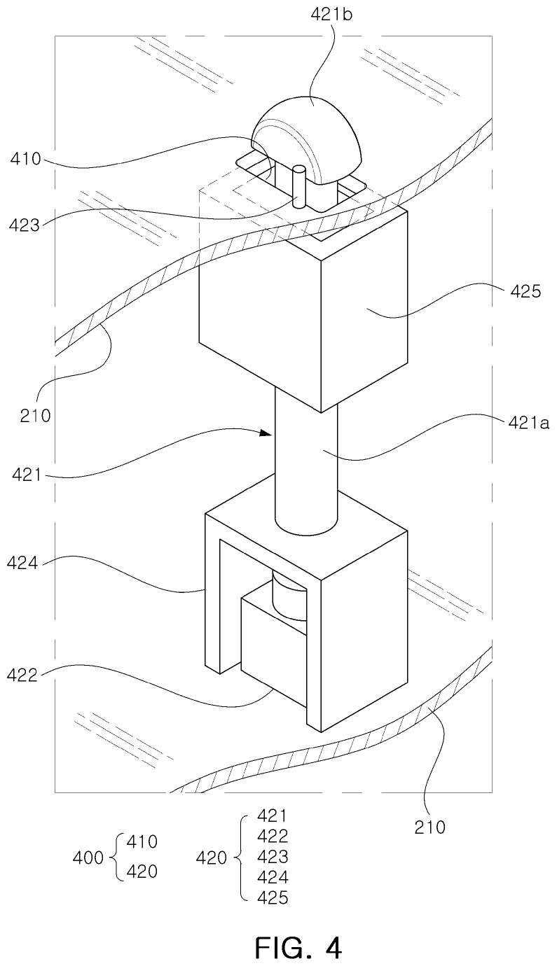

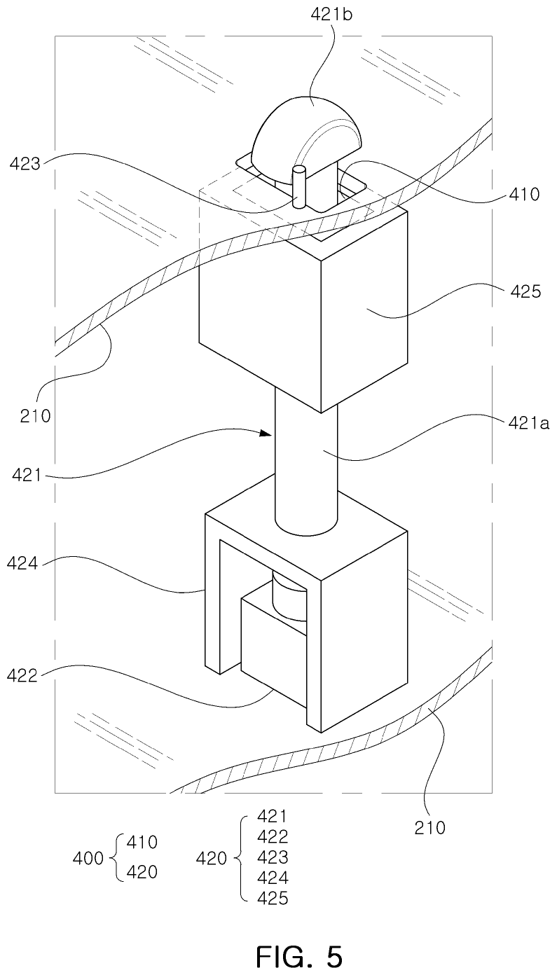

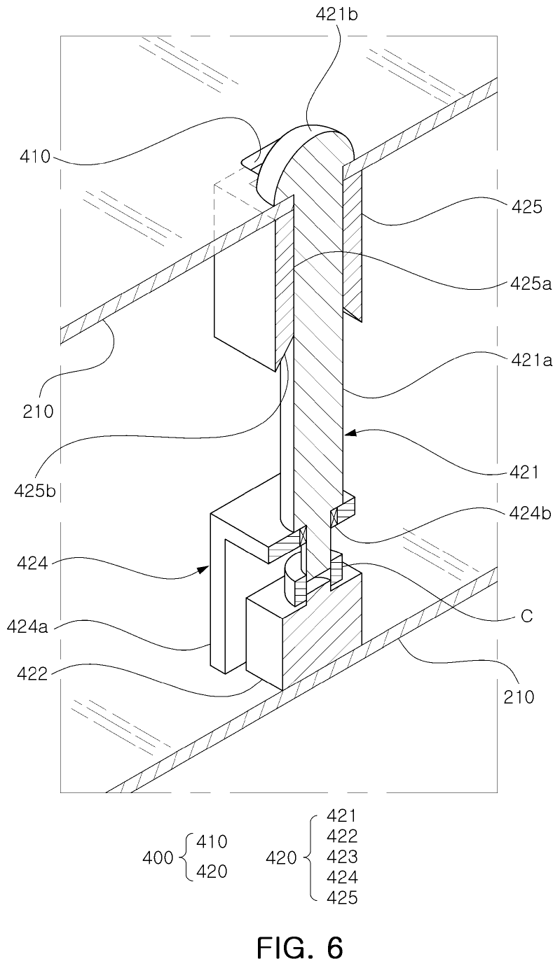

FIG. 1 is a view illustrating an overhead hoist transport facility according to an embodiment of the present disclosure, FIGS. 2 and 3 are enlarged views of a unit hanging apparatus when a hand unit descends and ascends in the overhead hoist transport facility of FIG. 1, and FIGS. 4 to 6 are cross-sectional views illustrating rotating, descending, and hanging of a hanging pin in the unit hanging apparatuses of FIGS. 2 and 3.

Referring to the drawings, an overhead hoist transport facility according to an embodiment of the present disclosure may include a rail R and an overhead hoist transport 1000.

The rail R may be installed on a ceiling of a semiconductor manufacturing line. To manufacture a semiconductor, many substrate processing processes should be performed. To perform these many substrate processing processes, many movements of substrates may be required between each process, and thus, the rail R may be installed for this purpose. The rail R may provide a travel path of the overhead hoist transport 1000, and in this case, the travel path may include a straight path and a curved path.

The overhead hoist transport 1000 may be disposed on the rail R, and may move along the rail R.

Specifically, the overhead hoist transport 1000 may include a travelling unit 100, a hoist unit 200, a hand unit 300, and a unit hanging apparatus 400.

The travelling unit 100 may be configured to travel along the rail R, and may travel on the rail R by rotation of a driving wheel 101 respectively attached to both side portions thereof.

In addition, the hoist unit 200 may be installed below the travelling unit 100, and may have a hoist belt 220. For example, in the hoist unit 200, a hoist belt 220 may be wound, and when the hoist unit 200 is in operation, the hoist belt 220 may be unwound or wound.

In addition, the hand unit 300 may be configured to grip a carrier 1 such as a FOUP on which substrates are loaded. The hand unit 300 may be disposed to suspend from the hoist belt 220 of the hoist unit 200. The hand unit 300 may ascend and descend, as the hoist belt 220 of the hoist unit 200 may be wound and unwound.

The unit hanging apparatus 400 may be formed in the hoist unit 200 and the hand unit 300.

In this case, the unit hanging apparatus 400 may be configured to hang the hand unit 300 on the hoist unit 200.

The unit hanging apparatus 400 may include a through-hole 410 and a hanging unit 420.

The through-hole 410 may be formed in a hoist body 210 of the hoist unit 200. This through-hole 410 may be configured to be formed vertically in the hoist body 210.

In addition, the hanging unit 420 may be formed on the hand unit 300, and may include a hanging pin 421.

The hanging pin 421 may be configured to pass through the through-hole 410 to be hung on the hoist body 210, to cause the hand unit 300 to be hung by the hoist unit 200.

Specifically, the hanging unit 420 may include the hanging pin 421, mentioned above, and a driving member 422.

The hanging pin 421 may be disposed vertically on an upper side of the hand unit 300. For example, the hanging pin 421 may be configured to be vertically disposed to correspond to the through-hole 410 formed vertically in the hoist body 210.

In addition, the driving member 422 may be installed on the hand unit 300, and may be configured to be connected to the hanging pin 421 and rotate the hanging pin 421. For example, the driving member 422 may be connected to a lower end portion of the hanging pin 421, and the hanging pin 421 may rotate when the driving member 422 is operated. In this case, in the driving member 422, a driving shaft 422a may be connected to the lower end portion of the hanging pin 421 by a coupling (C). Furthermore, the driving member 422 may utilize a driving motor, but is not limited thereto, and any conventional configuration may be utilized as long as it may be a driving source capable of rotating the hanging pin 421.

The hanging pin 421 may be configured to pass through the through-hole 410, rotate, and be hung on an upper edge of the through-hole 410 when the hanging unit descends.

Specifically, the hanging pin 421 may include a pin body 421a and a pin head 421b.

The pin body 421a may be formed in a cylindrical shape.

In addition, the pin head 421b may be formed on an upper end portion of the pin body 421a, and may be configured to be formed to laterally extend more than the pin body 421a.

In addition, the through-hole 410 may have a transverse cross-sectional area through which the pin head 421b passes, and a transverse cross-section corresponding to a transverse cross-section of the pin head 421b such that the pin head 421b can not pass through the through-hole 410 when pin head 421b descends after passing through the through-hole 410 and rotating. That is, the through-hole 410 has a cross-sectional shape that allows the pin head 421b to pass through, but prevents the pin head 421b from passing through in the reverse direction after passing through and rotating.

For example, the through-hole 410 may be formed in a shape corresponding to the transverse cross-section of the pin head 421b, and may be formed to be relatively long in one direction horizontally and relatively short in the other direction, perpendicular to the one direction.

As a result, the pin head 421b of the hanging pin 421 may pass through the through-hole 410, such that the hanging pin 421 may smoothly ascend and descend through the through-hole 410. In addition, due to a structure of the through-hole 410 described above, when the pin head 421b passes through the through-hole 410, rotates, and then descends, the pin head 421b may not pass through the through-hole 410 and may be hung on the upper edge of the through-hole 410.

In this case, penetration of the hanging pin 421 into the through-hole 410 may be achieved by winding the hoist belt 220 of the hoist unit 200 to ascend the hand unit 300. In addition, rotation of the hanging pin 421 may be achieved by operating the driving member 422. Furthermore, descending of the hanging pin 421 may be achieved by unwinding the hoist belt 220 of the hoist unit 200 to descend the hand unit 300.

In addition, the pin head 421b may be configured to be formed to taper in an upward direction. As an example, the pin head 421b may have an upwardly curved shape, i.e., an upwardly convex shape, as illustrated.

Due thereto, when the pin head 421b is inserted into the through-hole 410 to pass through the through-hole 410, the pin head 421b may be easily inserted into the through-hole 410, due to the structure described above.

In addition, the hanging unit 420 may further include a guide member 425.

The guide member 425 may be installed in a lower portion of the through-hole 410 in the hoist body 210, and may have a guide hole 425a guiding the hanging pin 421 to the through-hole 410. In a state in which the hanging pin 421 is located spaced apart from a lower side of the through-hole 410, when the hanging pin 421 is inserted into the through-hole 410, the hanging pin 421 may be guided to reach the through-hole 410 by the guide member 425 located between the hanging pin 421 and the through-hole 410.

In addition, an internal space of a lower opening 425b of the guide hole 425a may be formed to expand in a downward direction to guide introduction of the hanging pin 421. As a result, when the hanging pin 421 is inserted into the through-hole 410 to pass through the through-hole 410, the hanging pin 421 may be easily inserted into the through-hole 410 due to the structure described above.

The hanging unit 420 may further include a stopper 423.

The stopper 423 may be formed on the hoist body 210 to limit rotation of the hanging pin 421. The stopper 423 may be formed in a certain position of a rotational route of the hanging pin 421 in the hoist body 210, such that the hanging pin 421 may rotate at a certain angle and the rotation of the hanging pin 421 may be blocked by the stopper 423. For example, the stopper 423 may be located in a position in which rotation is blocked after the hanging pin 421 rotates at a 90-degree angle, such that the rotation may be stopped in a position in which the hanging pin 421 is hung on the upper edge of the through-hole 410.

In addition, the hanging unit 420 may further include a connecting bracket 424.

The connecting bracket 424 may be configured to connect the hanging pin 421 and the hand unit 300.

The hanging pin 421 may receive load of the hand unit 300, and the load may be transmitted through the connecting bracket 424, not the driving member 422. For example, since load of the hand unit 300 may be transmitted to the hanging pin 421 through the connecting bracket 424, the load transmission of the hand unit 300 may be achieved through a solid structure.

In this case, the connecting bracket 424 may include a bracket body 424a and a bearing 424b.

The bracket body 424a may be installed in the hand unit 300, and a bracket hole through which the hanging pin 421 passes may be formed. In addition, the bearing 424b may be installed in the bracket hole, and the hanging pin 421 may be rotatably connected to the connecting bracket 424.

In this manner, the hanging pin 421 may be connected to the bracket body 424a through the bearing 424b, to be rotatable while being firmly connected to the connecting bracket 424.

In addition, in the configurations as described above, the through-hole 410 may be provided as a plurality of through-holes, and the plurality of through-holes may be disposed at regular intervals from each other in the hoist body 210, and the hanging unit 420 may be provided as a plurality of hanging units, and the plurality of hanging units may be disposed at regular intervals from each other on the hand unit 300 to correspond to the plurality of through-holes 410.

Due to the plurality of through-holes 410 and the plurality of hanging units 420, the hand unit 300 having a relatively large size, as compared to the hanging unit 420, may be stably and firmly hung on the hoist unit 200.

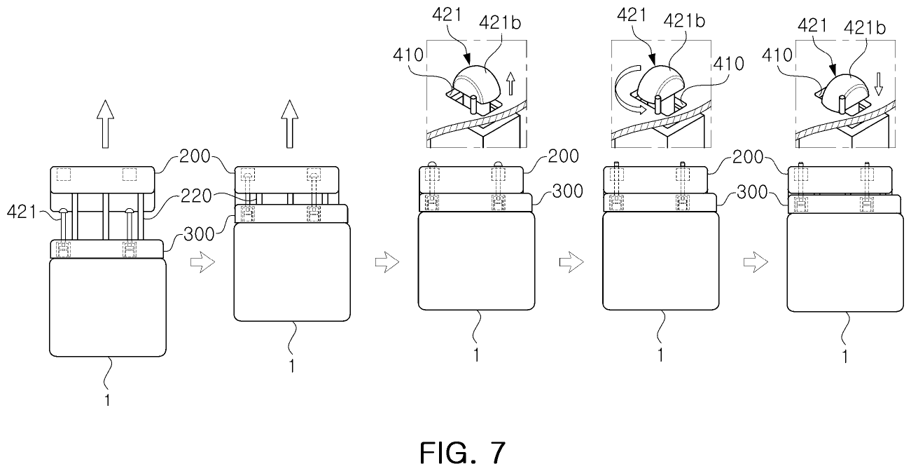

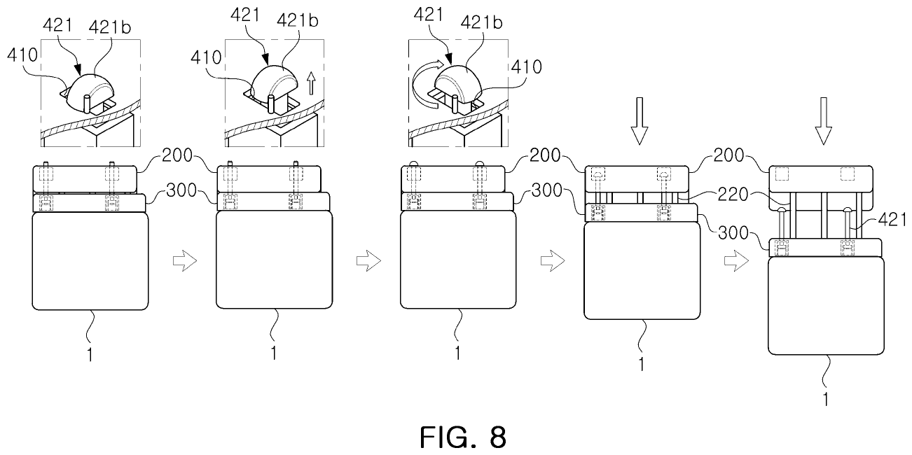

FIG. 7 is a view illustrating a process in which the hand unit of FIG. 2 ascends and is then hung on a hoist unit, and FIG. 8 is a view illustrating a process in which the hand unit of FIG. 3 is released from a hoist unit and then descends.

A process of hanging the hand unit 300 on the hoist unit 200, after the hand unit 300 grips the carrier 1 and before the carrier 1 is transported, will be described with reference to FIG. 7 as follows.

First, as illustrated in a first drawing and a second drawing from a left side, as the hoist belt 220 of the hoist unit 200 is wound to ascend the hand unit 300, the hanging pin 421 may be inserted into the through-hole 410.

Afterwards, as illustrated in a third drawing from the left side, the hanging pin 421 may continue to ascend such that the pin head 421b ascends slightly higher than the upper edge of the through-hole 410 located on a hanging height.

Next, as illustrated in a fourth drawing from the left side, the hanging pin 421 may rotate counterclockwise by the driving member 422, such that the hanging pin 421 rotates to a position in which the pin head 421b may be hung on the upper edge of the through-hole 410.

Finally, as illustrated in a fifth drawing from the left side, as the hoist belt 220 of the hoist unit 200 is unwound to descend the hand unit 300, the hanging pin 421 may be hung on the upper edge of the through-hole 410 located on an hanging height.

A process of releasing the hand unit 300 from the hoist unit 200, after the hand unit 300 transports the carrier 1 and before putting down the carrier 1, will be described with reference to FIG. 8 as follows.

First, as illustrated in a first drawing and a second drawing from a left side, as the hoist belt 220 of the hoist unit 200 is wound to ascend slightly the hand unit 300, the hanging pin 421 may be slightly raised from the upper edge of the through-hole 410, to enter a released state.

Then, as illustrated in a third drawing from the left side, the hanging pin 421 may rotate clockwise by the driving member 422, causing the pin head 421b to move to a position corresponding to a pin head hole 410b.

Finally, as illustrated in fourth and fifth drawings from the left side, as the hoist belt 220 of the hoist unit 200 is unwound to descend the hand unit 300, the hanging pin 421 may come out from the through-hole 410.

As a result, the present disclosure may include the hanging unit 420 having the hanging pin 421 hung on the hoist body 210 such that the hand unit 300 is hung by the hoist unit 200, to prevent a hoist motor of the hoist unit 200 from being driven, thereby eliminating load of a stall torque of the hoist motor. Furthermore, deterioration of the hoist motor may be prevented, and requirements of the hoist motor may be reduced to lower costs.

In addition, since the hanging pin 421 of the hanging unit 420 of the present disclosure may be replaced with a conventional alignment pin aligning the hand unit 300 with respect to the hoist unit 200, the hanging pin 421 may perform a role of aligning the hand unit 300 as well as a role of hanging the hand unit 300.

The present disclosure may include a hanging unit having a hanging pin hung on a hoist body such that a hand unit is hung by a hoist unit, to prevent a hoist motor of the hoist unit from being driven, thereby eliminating load of a stall torque of the hoist motor. Furthermore, deterioration of the hoist motor may be prevented, and requirements of the hoist motor may be reduced to lower costs.

In addition, since a hanging pin of a hanging unit of the present disclosure may be replaced with a conventional alignment pin aligning a hand unit with respect to a hoist unit, the hanging pin may perform a role of aligning the hand unit as well as a role of hanging the hand unit.

While example embodiments have been illustrated and described above, it will be apparent to those skilled in the art that modifications and variations could be made without departing from the scope of the present disclosure as defined by the appended claims.

What is claimed is:

1. A unit hanging apparatus comprising:
a through-hole formed in a hoist body of a hoist unit; and
a hanging unit formed in a hand unit suspended from a hoist belt of the hoist unit, and having a hanging pin that passes through the through-hole and is hung on the hoist body so that the hand unit is hung on the hoist unit.

2. The unit hanging apparatus of claim 1, wherein the through-hole is disposed vertically,
the hanging unit includes:
the hanging pin disposed vertically on an upper side of the hand unit; and
a driving member installed on the hand unit and connected to the hanging pin to rotate the hanging pin, and
the hanging pin is hung on an upper edge of the through-hole when the hanging pin rotates and descends after passing through the through-hole.

3. The unit hanging apparatus of claim 2, wherein the hanging pin comprises:
a pin body formed in a cylindrical shape; and
a pin head formed on an upper end portion of the pin body and formed to extend laterally more than the pin body.

4. The unit hanging apparatus of claim 3, wherein the through-hole has a cross-sectional shape that allows the pin head to pass through, but prevents the pin head from passing through in the reverse direction after passing through and rotating.

5. The unit hanging apparatus of claim 3, wherein the pin head is formed to taper in an upward direction.

6. The unit hanging apparatus of claim 2, wherein the hanging unit further comprises a guide member installed in a lower portion of the through-hole in the hoist body and having a guide hole guiding the hanging pin to the through-hole.

7. The unit hanging apparatus of claim 6, wherein an internal space of a lower opening of the guide hole is formed to expand in a downward direction to guide introduction of the hanging pin.

8. The unit hanging apparatus of claim 2, wherein the hanging unit further comprises a stopper formed on the hoist body to limit rotation of the hanging pin.

9. The unit hanging apparatus of claim 2, wherein the hanging unit further comprises a connecting bracket connecting the hanging pin and the hand unit,
wherein the connecting bracket includes:
a bracket body installed in the hand unit and having a bracket hole formed through which the hanging pin passes; and
a bearing installed in the bracket hole and to which the hanging pin is rotatably connected.

10. The unit hanging apparatus of claim 2, wherein the through-hole is provided as a plurality of through-holes, the plurality of through-holes are disposed at a predetermined interval from each other in the hoist body, and
the hanging unit is provided as a plurality of hanging units, the plurality of hanging units are disposed at a predetermined interval from each other on the hand unit to correspond to the plurality of through-holes.

11. An overhead hoist transport comprising:
a travelling unit;
a hoist unit installed on the travelling unit and having a hoist belt;
a hand unit suspended from the hoist belt; and
a unit hanging apparatus formed in the hoist unit and the hand unit such that the hand unit is hung on the hoist unit,
wherein the unit hanging apparatus includes:
a through-hole formed in a hoist body of the hoist unit; and
a hanging unit having a hanging pin formed in the hand unit and passing through the through-hole and hung on the hoist body.

12. The overhead hoist transport of claim 11, wherein the hanging unit comprises:
the hanging pin disposed vertically on an upper side of the hand unit; and
a driving member installed on the hand unit and connected to the hanging pin to rotate the hanging pin, and
the hanging pin is hung on an upper edge of the through-hole when the hanging pin rotates and descends after passing through the through-hole.

13. The overhead hoist transport of claim 12, wherein the hanging pin comprises:
a pin body formed in a cylindrical shape; and
a pin head formed on an upper end portion of the pin body and formed to extend laterally more than the pin body.

14. The overhead hoist transport of claim 13, wherein the through-hole has a cross-sectional shape that allows the pin head to pass through, but prevents the pin head from passing through in the reverse direction after passing through and rotating.

15. The overhead hoist transport of claim 13, wherein the pin head is formed to taper in an upward direction.

16. The overhead hoist transport of claim 12, wherein the hanging unit further comprises a guide member installed in a lower portion of the through-hole in the hoist body and having a guide hole guiding the hanging pin to the through-hole, and
an internal space of a lower opening of the guide hole is formed to expand in a downward direction to guide introduction of the hanging pin.

17. The overhead hoist transport of claim 12, wherein the hanging unit further comprises a stopper formed on the hoist body to limit rotation of the hanging pin.

18. An overhead hoist transport facility comprising:
a rail installed on a ceiling; and
an overhead hoist transport disposed on the rail, wherein the overhead hoist transport includes travelling unit travelling along the rail; a hoist unit installed on the travelling unit and having a hoist belt; a hand unit suspended from the hoist belt; and a unit hanging apparatus formed in the hoist unit and the hand unit such that the hand unit is hung on the hoist unit,
wherein the unit hanging apparatus includes a through-hole formed in a hoist body of the hoist unit; and a hanging unit having a hanging pin formed in the hand unit and passing through the through-hole and hung on the hoist body, wherein the hanging unit includes the hanging pin disposed vertically on an upper side of the hand unit; a driving member installed on the hand unit and connected to the hanging pin to rotate the hanging pin; and a connecting bracket connecting the hanging pin and the hand unit, and
wherein the hanging pin is hung on an upper edge of the through-hole when the hanging pin rotates and descends after passing through the through-hole.

19. The overhead hoist transport facility of claim 18, wherein the hanging pin comprises:
a pin body formed in a cylindrical shape; and
a pin head formed on an upper end portion of the pin body and formed to extend laterally more than the pin body,
wherein the through-hole has a cross-sectional shape that allows the pin head to pass through, but prevents the pin head from passing through in the reverse direction after passing through and rotating.

20. The overhead hoist transport facility of claim 19, wherein the pin head is formed to taper in an upward direction,
wherein the hanging unit further includes a guide member installed in a lower portion of the through-hole in the hoist body and having a guide hole guiding the hanging pin to the through-hole,
wherein an internal space of a lower opening of the guide hole is formed to expand in a downward direction to guide introduction of the hanging pin, and
wherein the hanging unit further includes a stopper formed on the hoist body to limit rotation of the hanging pin.
